(19) United States
(12) Patent Application Publication
(10) Pub. No.: US 2009/0311856 A1
(43) Pub. Date: Dec. 17, 2009

(54) FLASH MEMORY DEVICE HAVING RECESSED FLOATING GATE AND METHOD FOR FABRICATING THE SAME

(76) Inventor: Jae-Hong Kim, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/546,594

(22) Filed: Aug. 24, 2009

Related U.S. Application Data
(62) Division of application No. 11/416,838, filed on May 2, 2006.

(30) Foreign Application Priority Data
Nov. 30, 2005 (KR) 2005-0115670

(51) Int. Cl. H01L 21/28

(52) U.S. Cl. 438/589; 438/594; 257/E21.209

(57) ABSTRACT

A flash memory device and a method for fabricating the same are provided. The flash memory device includes: an active region having a plurality of surface regions and a plurality of recess regions formed lower than the surface regions; a tunnel oxide layer formed over the recess regions; a plurality of recessed floating gates formed over the tunnel oxide layer to be buried into the recess regions; a plurality of dielectric layers over the recessed floating gates; and a plurality of control gates over the dielectric layers.

### FIELD OF THE INVENTION

The present invention relates to a method for fabricating a semiconductor device; and more particularly, to a flash memory device and a method for fabricating the same.

### DESCRIPTION OF RELATED ARTS

Recently, a high integration technology of a memory device has been actively studied to develop a memory device with a high capacitance capable of storing, programming and erasing a large amount of data.

If a design rule is decreased for a high integration, a gate length is decreased. Accordingly, a doping concentration is increased while performing a threshold voltage adjustment ion-implantation capable of controlling a threshold voltage.

Typically, if the doping concentration implanted within a substrate is increased, an electric field between source/drains and a junction leakage current are increased, and a short channel effect such as a drain induced barrier lowering (DIBL) phenomenon is generated. A basic method to prevent the short channel effect from being generated is to decrease a doping concentration of a substrate or increase an effective gate length.

FIG. 1 is a top view illustrating a typical flash memory device. FIGS. 2A and 2B are cross-sectional views illustrating FIG. 1 cut along a line I-I′ and FIG. 1 cut along a line II-II′ respectively.

As shown in FIG. 1, a plurality of device isolation layers 12 are placed in a substrate 11 spaced apart a predetermined distance in the same direction. A plurality of control gates CG 16 covering a plurality of floating gates FG 14 formed in an active region 11A between the device isolation layers 12 are formed in a direction perpendicular to the device isolation layers 12. Herein, the control gates CG 15 are practically placed in the direction perpendicular to the device isolation layer 12, and the floating gates FG 14 are formed only in the intersection point between the control gates CG 16 and the active region 11A.

Referring to FIGS. 2A and 2B to examine the floating gates FG 14, a plurality of device isolation layers 12 with a trench structure are formed with a predetermined distance in a substrate 11. At this time, an active region 11A is formed between the device isolation layers 12, and the device isolation layers 12 have a higher height than the active region 11A.

A plurality of stack structures formed by stacking a tunnel oxide layer 13 and the floating gates 14 are formed over the active region 11A. A plurality of oxide/nitride oxide (ONO) layers 15 are formed over an entire surface including the floating gates FG 14, and a plurality of control gates CG 16 are formed over the ONO layers 15. At this time, the control gates CG 16 cover the floating gates 14 and are placed in a line shape covering the device isolation layers 12.

As for the conventional flash memory device, a gate line formed with a floating gate and a control gate is formed over a flat active region. Thus, the conventional flash memory device becomes a planar type structure.

However, in the conventional planar gate structure, an effective gate length is decided by a line width of the floating gate and thus, the effective gate length is very short. Accordingly, a short channel effect (SCE) is increased, and thus, it is difficult to make a highly integrated NAND flash memory device.

### SUMMARY OF THE INVENTION

It is, therefore, an object of the present invention to provide a flash memory device capable of preventing a doping concentration of a substrate from being increased as a device has been integrated and securing an electrical property of the device by increasing an effective gate length, and a method for fabricating the same.

In accordance with one aspect of the present invention, there is provided a flash memory device including: an active region having a plurality of surface regions and a plurality of recess regions formed lower than the surface regions; a tunnel oxide layer formed over the recess regions; a plurality of recessed floating gates formed over the tunnel oxide layer to be buried into the recess regions; a plurality of dielectric layers over the recessed floating gates; and a plurality of control gates over the dielectric layers.

In accordance with another aspect of the present invention, there is provided a method for fabricating a flash memory device including: forming a plurality of device isolation layers with a trench structure and a height greater than that of a surface of an active region in a substrate; forming a plurality of recess patterns by etching regions in which floating gates are to be formed in the active region between the device isolation layers to a predetermined depth; forming a tunnel oxide layer over the recess patterns; forming a plurality of recessed floating gates buried into the recess patterns over the tunnel oxide layer; and forming a plurality of stack structures by stacking a plurality of dielectric layers and a plurality of control gates in a direction perpendicular to the device isolation layers to cover upper portions of the recessed floating gates.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a top view illustrating a typical flash memory device;

FIGS. 2A and 2B are cross-sectional views illustrating FIG. 1 cut along a line I-I′ and a line II-II′ respectively;

FIG. 3 is a top view illustrating a flash memory device in accordance with a specific embodiment of the present invention;

FIGS. 4A and 4B are cross-sectional views illustrating FIG. 3 cut along a line I-I′ and a line II-II′ respectively; and

FIGS. 5A to 5H are cross-sectional views illustrating a method for fabricating a flash memory device in accordance with a specific embodiment of the present invention.

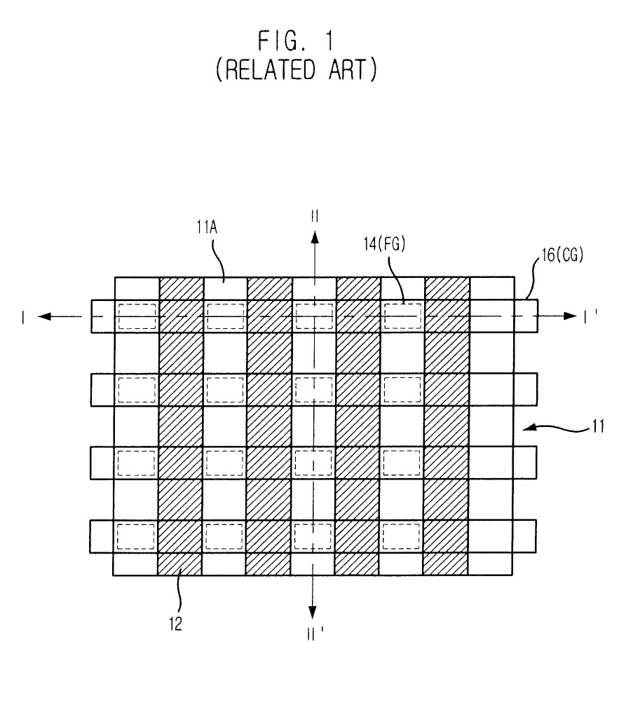

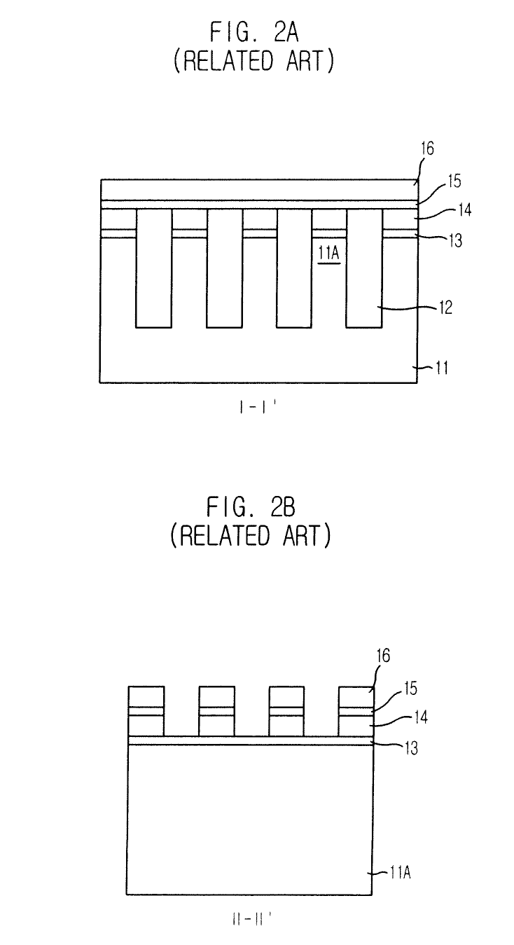

### DETAILED DESCRIPTION OF THE INVENTION

Hereinafter, detailed descriptions of certain embodiments of the present invention will be provided with reference to the accompanying drawings.

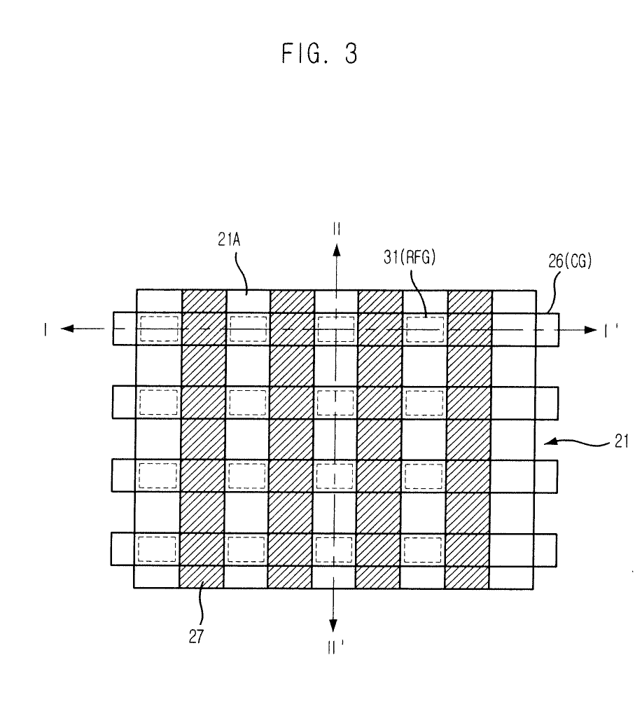

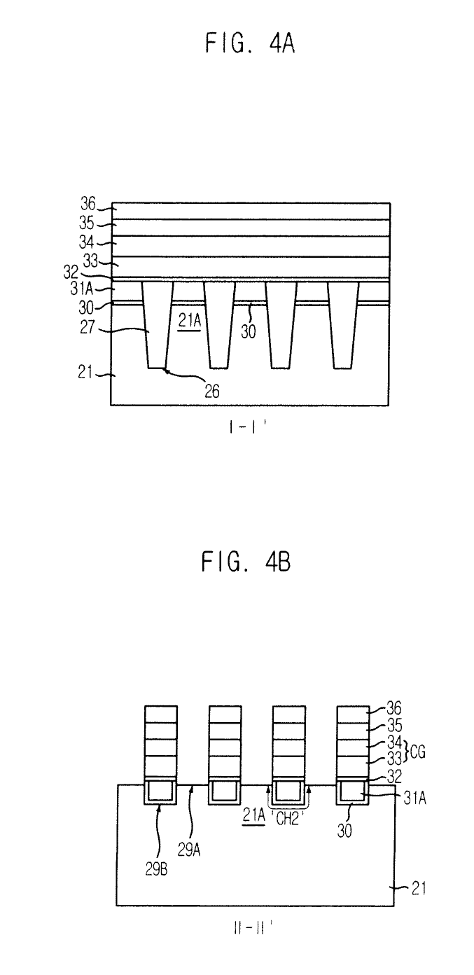

FIG. 3 is a top view illustrating a flash memory device in accordance with a specific embodiment of the present invention. FIGS. 4A and 4B are cross-sectional views illustrating FIG. 3 cut along a line I-I′ and a line II-II′ respectively.

As shown in FIG. 3, a plurality of device isolation layers 27 are formed in a substrate 21 spaced apart a predetermined distance in the same direction. A plurality of recessed floating gates RFG 31A are formed in recess patterns provided in an active region 21A between the device isolation layers 27. A plurality of control gates CG 26 covering the recessed floating gates RFG 31A are placed in a direction perpendicular to the device isolation layers 27.

Referring to FIGS. 4A and 4B to examine the recessed floating gates RFG 31A, a plurality of device isolation layers 27 with trench structures are formed in a substrate 21 spaced apart a predetermined distance. At this time, an active region 21A is formed between the device isolation layers 27, and each of the device isolation layers 27 is formed with a height higher than a surface of the active region 21A.

The active region 21A has a plurality of recess patterns 29B. A plurality of stack structures, each formed by stacking a tunnel oxide layer 30 and a recessed floating gate RFG 31A, are formed inside the recess patterns 29B. Herein, a surface of the recessed floating gates RFG 31A is identical to a surface of the device isolation layers 27 insulating a portion between recessed floating gates RFG 31A. The recessed floating gates RFG 31A are formed with polysilicon. The recess patterns 29B are insulated from each other by the device isolation layers 27 in a longitudinal direction to a control gate CG, and are isolated from each other by the active region 21A in a longitudinal direction to the active region 21A.

An oxide/nitride/oxide (ONO) layer 32, a second polysilicon layer 33, a tungsten silicide layer 34, a silicon oxynitride layer 35 and a hard mask oxide layer 36 are sequentially stacked over each of the recessed floating gates RFG 31A. Herein, each of control gates CG is formed stacking the second polysilicon layer 33 and the tungsten silicide layer 34.

As shown in FIGS. 3, 4A and 4B, floating gates FG are formed in the recessed floating gates RFG 31A buried into the recess patterns 29B. Thus, an effective gate length defined by each of the recessed floating gates 31A becomes CH2. Herein, CH2 is longer than an effective gate length of the conventional planar type structure by a depth of the individual recess pattern 29B, i.e., practically twice as long as the depth of the individual recess pattern 29B. That is, it is possible to increase an effective gate length without increasing a doping concentration of the substrate.

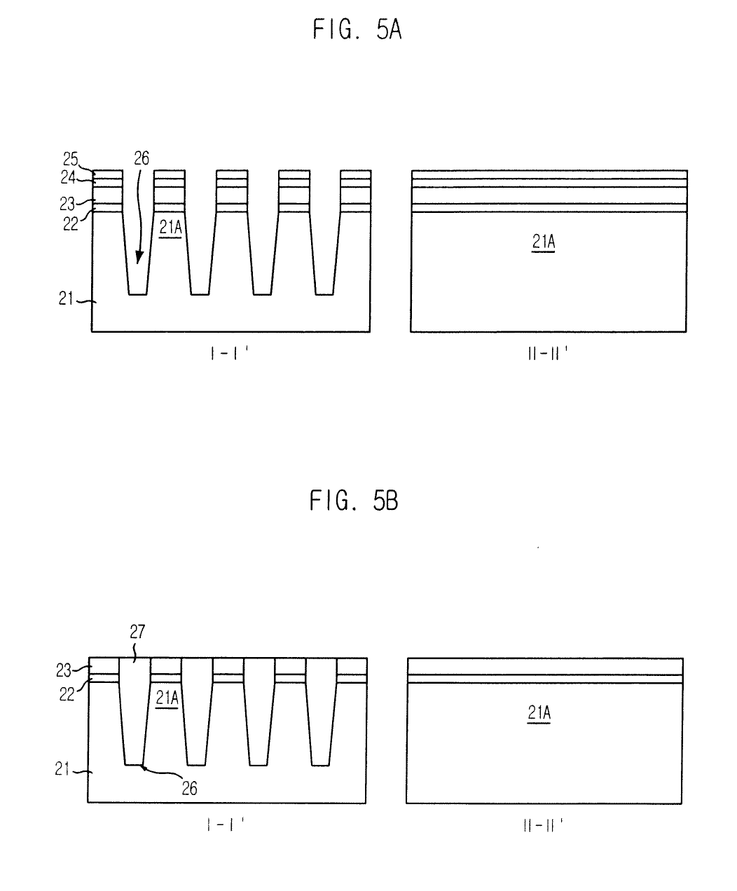

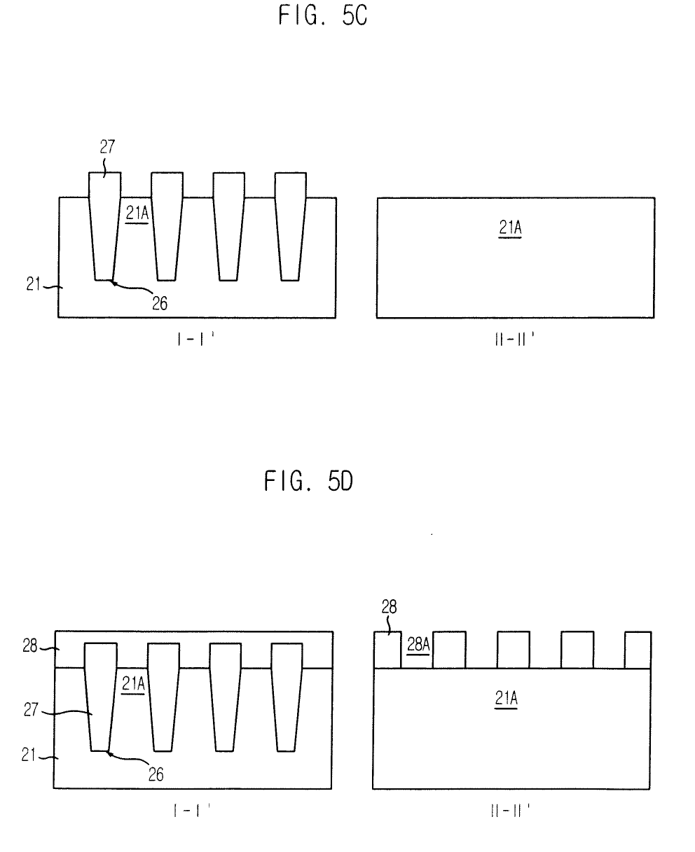

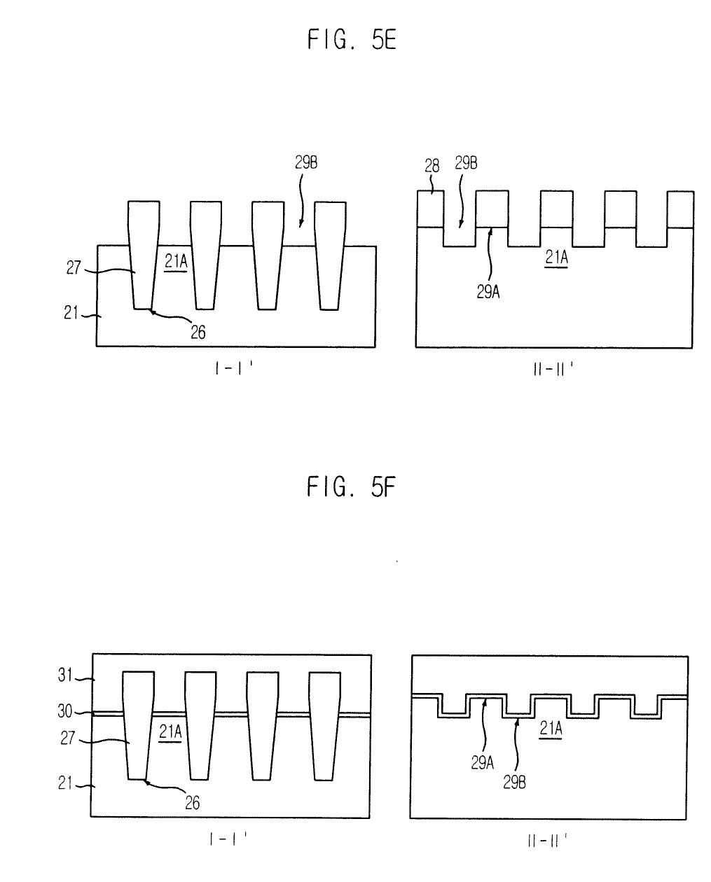

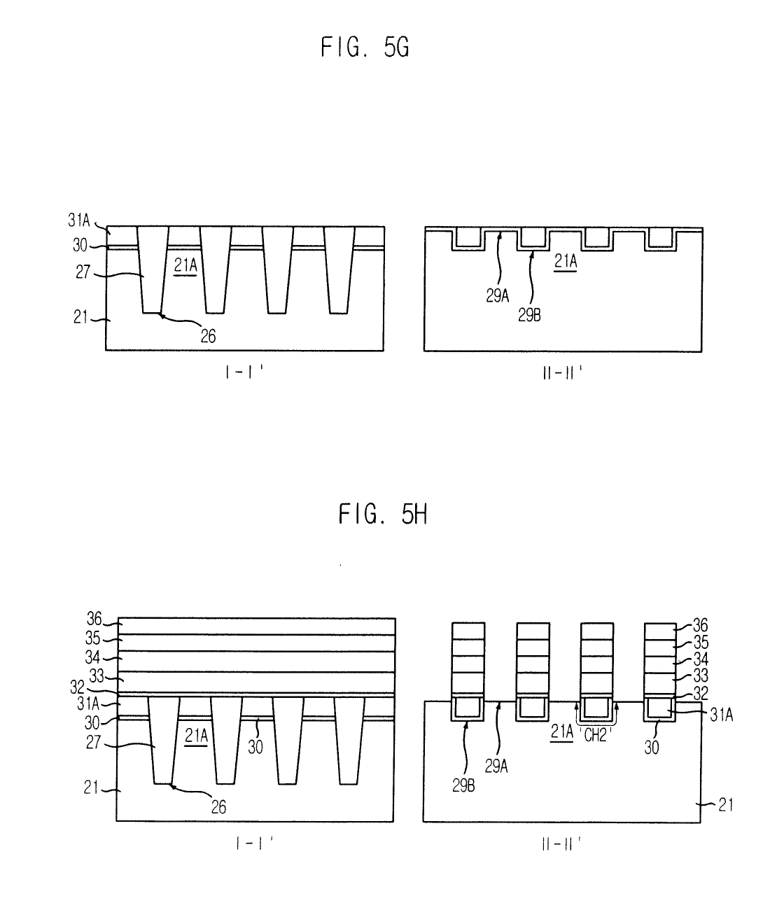

FIGS. 5A to 5H are cross-sectional views illustrating a method for fabricating a memory device in accordance with a specific embodiment of the present invention. Among FIGS. 5A to 5H, the figures placed in the left side are cross-sectional views illustrating FIG. 3 cut along the line I-I′ and the figures placed in the right side are cross-sectional views illustrating FIG. 3 cut along the line II-II′.

As shown in FIG. 5A, a patterned threshold voltage (Vt) screen oxide layer 22, a patterned ISO nitride layer 23, a patterned ISO oxide layer 24, and a patterned ISO hard mask 25 are sequentially stacked over a patterned substrate 21.

Although not shown, the process of forming the patterned threshold voltage (Vt) screen oxide layer 22, the patterned ISO nitride layer 23, the patterned ISO oxide layer 24, and the patterned ISO hard mask 25, and the patterned substrate 21 are explained hereinafter.

A Vt screen oxide layer, an ISO nitride layer, an ISO oxide layer, and an ISO hard mask are sequentially deposited over a substrate to perform a shallow trench isolation (STI) process. Herein, the substrate is defined with a cell array region and a peripheral region.

The Vt screen oxide layer is deposited to function as a thermal oxide layer in a thickness ranging from approximately 50 Å to approximately 100 Å in a diffusion furnace at a temperature of approximately 900° C. and an oxide atmosphere.

The ISO nitride layer is deposited with a thickness of approximately 500 Å at a temperature of approximately 760° C. with supply of a pressure of approximately 0.35 torr by flowing approximately 50 cc of nitrogen (N₂), approximately 90 cc of dichlorosilane (SiH₂Cl₂), and approximately 90 cc of ammonia (NH₃).

Both the ISO oxide layer and the ISO hard mask are formed in a thickness of approximately 300 Å. The ISO hard mask is formed by using silicon oxynitride (SiON).

Next, the ISO hard mask is patterned by using an ISO mask (not shown) and afterwards, the ISO mask is stripped. Herein, the patterned ISO hard mask is denoted with a reference numeral 25. The ISO oxide layer, the ISO nitride layer, and the Vt screen oxide layer are sequentially etched by using the patterned ISO hard mask 25 as an etch mask. Herein, the patterned ISO oxide layer, the patterned ISO nitride layer, and the patterned Vt screen oxide layer are denoted with reference numerals 24, 23, and 22 respectively.

Next, the substrate exposed after etching the Vt screen oxide layer is etched to a predetermined depth. Herein, the patterned substrate is denoted as a reference numeral 21. Then, a plurality of trenches 26 for device isolation are formed and a portion except for the trenches 26 is defined as an active region 21A. At this time, the trenches 26 are formed with a depth of approximately 2,000 Å. The etching process of the ISO hard mask to the substrate is carried out in-situ by using a dry etching process. Etchant used in the etching process for forming the trenches 26 comprises a fluorine-based gas selected from the group consisting of tetrafluoromethane (CF₄), hexafluoroethane (C₂F₆), octafluorocyclobutane (C₄F₈), hexafluorobutadiene (C₄F₆), octafluorocyclopentene (C₅F₈), trifluoromethane (CF₃H), Carbon fluoride hydride (CF₂H₂), methy fluoride (CFH₃), pentafluoroethane (C₂HF₅), nitrogen trifluoride (NF₃), sulphur hexafluoride (SF₆) and CF₃Cl. A gas additive to the etchant is one of hydrogen (H₂) and oxygen (O₂).

As shown in FIG. 5B, a gap-fill layer 27 is deposited until trenches 26 are filled. The gap-fill layer 27 is formed with a high density plasma oxide layer. At this time, a deposition thickness of the gap-fill insulation layer 27 should be optimized to isolate the cell region and the peripheral region without generating a dishing phenomenon or erosion during a subsequent chemical mechanical polishing (CMP) process. For instance, the gap-fill layer 27 is deposited with a thickness ranging from approximately 5,000 Å to approximately 8,000 Å. Meanwhile, after the gap-fill insulation layer 27 made of the high density plasma oxide layer is deposited, an annealing is performed at a temperature of 1,050° C. in a nitrogen atmosphere for approximately 30 minutes and thus, quality of the layer becomes dense.

A first CMP process is performed by using silica slurry to remove a high height difference over the active region 21A. A second CMP process is performed by using ceria slurry. Thus, uniformity of the gap-fill insulation layer 27 is improved in the cell array region and the peripheral region, and the gap-fill insulation layer 27 is isolated from each other.

During the CMP process, the ceria slurry has a high polishing selectivity of the gap-fill insulation layer 27 formed with the high density plasma oxide layer to the patterned ISO nitride layer 23 formed with the silicon nitride layer. However, a height removing capability of the ceria slurry is lower than the silica slurry. Thus, a predetermined portion of the gap-fill insulation layer 27 is planarized in advance before using the ceria slurry to remove the height difference. Then, the gap-fill insulation layer 27 is isolated from each other by using the ceria slurry having high selectivity slurry (HSS).

During the CMP process performed twice, the patterned ISO layer 23 serves a role of a polishing stop layer. Accordingly, during the CMP process, the gap-fill insulation layer 27, the patterned ISO hard mask 25 and the patterned ISO oxide layer 24 are polished.

Hereinafter, the isolated gap-fill insulation layer 27 is referred to as device isolation layers 27. A surface of each of the device isolation layers 27 is higher than that of the active region 21A.

As shown in FIG. 5C, the patterned ISO layer 23 and the patterned Vt oxide layer 22 remaining after planarizing the device isolation layers 27 are stripped.

Herein, before stripping the patterned ISO nitride layer 23, the patterned ISO nitride layer 23 is dipped into a solution of buffered oxide etchant (BOE) to remove the device isolation layers 27 which may remain over the patterned ISO nitride layer 23 and then, stripped by using phosphoric acid (H₃PO₄) solution. Afterwards, the patterned Vt screen oxide layer 22 is stripped by using a solution of hydrogen fluoride (HF). At this time, a stripping time can be controlled not to generate a moat around a boundary region between a top corner of the active region 21A and the device isolation layers 27.

After the stripping process, the device isolation layers 27 are formed in a type insulting portions of the active region 21A, and the device isolation layers 27 are formed higher than the active region 21A.

As shown in FIG. 5D, a photoresist layer is formed over an entire surface of the resulting structure including the device isolation layers 27. The photoresist layer is patterned by performing a photo-exposure process and a developing process, thereby forming a recess mask 28. At this time, the recess mask 28 can be formed as a reverse mask of a control gate mask used to pattern a subsequent control gate. That is, the reverse mask exposes a gate material to be covered by the control gate mask and covers a portion to be etched. Typically, a portion covered by the control gate mask becomes a control gate after the etching process.

Accordingly, the recess mask 28 has an opening which opens an upper portion of the active region 21A and the device isolation layers 27 placed in a direction perpendicular to the control gate. For instance, the opening of the recess mask 28 is placed in a direction perpendicular to the device isolation layers 27 placed in the same direction to the opening of the recess mask 28.

As show in FIG. 5E, a plurality of recess patterns 29B are formed by etching predetermined portions of the active region 21A. At this time, the active region 21A is recessed to a predetermined depth by using the recess mask 28 formed in a direction perpendicular to the device isolation layers 27.

Accordingly, the active region 21A is classified into a plurality of surface regions 29A and the plurality of recess patterns 29B lower than the recess regions 21A. In more detail, predetermined portions of the active region 21A are recessed to have a predetermined distance, thereby forming the recess patterns 29B and the surface regions 29A between the recess patterns 29B. The recess patterns 29B are insulated by the device isolation layers 27 at a direction which a control gate is formed. Also, the recess patterns 29B have isolated structures since the recess patterns 29B are isolated from each other by each of the surface regions 29A at a direction of the active region 21A.

The most important factor in the etching process for forming the recess patterns 29B is an etch profile. A depth of the individual recess pattern 29B should be uniform and a horn should not be generated in inner edges of the profile of the individual recess pattern 29B.

For instance, etchant used in the etching process for forming the recess patterns 29B comprises a gas selected from the group consisting of CF₄ gas, C₂F₆ gas, C₄F₈ gas, C₄F₆ gas, C₅F₈ gas, CF₃H gas, CF₂H₂ gas, CFH₃ gas, C₂HF₅ gas, NF₃ gas, SF₆ gas, and CF₃Cl gas. Also, a gas additive to the etchant uses H₂ gas or O₂ gas. An etch target, i.e., a depth to be etched, ranges from approximately 800 Å to approximately 1,500 Å. If the etching process is performed with the above described condition, the horn is not generated.

As shown in FIG. 5F, the recess mask 28 is stripped.

A tunnel oxide layer 30 is formed over the surface regions 29A and the recess patterns 29B and then, a first polysilicon layer 31 is formed over the tunnel oxide layer 30. At this time, the tunnel oxide layer is formed with a thickness ranging from approximately 50 Å to approximately 100 Å. A thickness of the first polysilicon layer 31 ranges from approximately 1,000 Å to approximately 2,000 Å in consideration of a depth to be removed during a subsequent CMP process.

As shown in FIG. 5G, the first polysilicon layer 31 is planarized by performing a polysilicon CMP process to form plurality of floating gates 31A made of the first polysilicon. At this time, the floating gates 31A are isolated from each other by the device isolation layers 27.

Slurry used in the polysilicon CMP process has a very high selectivity of polysilicon to the tunnel oxide layer 30. The tunnel oxide layer 30 serves a role of a CMP barrier and thus, the patterned substrate 21 is not attacked and a dishing phenomenon, i.e., a dishing phenomenon with a thickness of approximately 50 Å, is minimized in upper portions of the floating gates 31A.

The aforementioned slurry has a very high etch selectivity of approximately 200 parts of polysilicon, i.e., approximately 200 parts to approximately 300 parts of polysilicon, to approximately 1 part of the tunnel oxide layer. This slurry having very high etch selectivity ratio has an etch selectivity of approximately 200 parts of polysilicon to approximately 1 part of the high density plasma oxide layer used as the device isolation layers 27.

As described above, the floating gates 31A are buried into the recess patterns 29B. Accordingly, hereinafter, the floating gates 31A are referred to as recessed floating gates 31A.

As shown in FIG. 5H, a patterned hard mask oxide layer 36, a patterned silicon oxynitride layer 35, a patterned tungsten silicide layer 34, a patterned second polysilicon layer 33 and a patterned oxide/nitride/oxide (ONO) layer 32 are formed over the recessed floating gates 31A. Although not shown, a process of forming the patterned hard mask oxide layer 36, the patterned silicon oxynitride layer 35, the patterned tungsten silicide layer 34, the patterned second polysilicon layer 33 and the patterned ONO layer 32 is explained hereinafter. An ONO layer, a second polysilicon layer, a tungsten silicide layer, a silicon oxynitride layer, and a hard mask oxide layer are sequentially formed over an entire surface of the resulting structure including the recessed floating gates 31A. Herein, when forming the ONO layer, oxygen (O) is deposited with a thickness ranging from approximately 30 Å to approximately 50 Å; nitrogen (N) is deposited with a thickness ranging from approximately 30 Å to approximately 50 Å; and oxygen (O) is deposited with a thickness ranging from approximately 50 Å to approximately 70 Å. The second polysilicon layer is deposited with a thickness of approximately 2,000 Å, and the tungsten silicide layer is deposited with a thickness ranging from approximately 1,000 Å to approximately 1,500 Å. The silicon oxynitride layer is deposited with a thickness ranging from approximately 200 Å to approximately 300 Å, and the hard mask oxide layer is deposited with a thickness ranging from approximately 1,500 Å to approximately 2,000 Å.

Next, the hard mask layer, the silicon oxynitride layer, the tungsten silicide layer, the second polysilicon layer, and the ONO layer are etched by performing an etching process using a control gate mask (not shown). Herein, the patterned hard mask layer, the patterned silicon oxynitride layer, the patterned tungsten silicide layer, the patterned second polysilicon layer, and the patterned ONO layer are denoted with reference numerals 36, 35, 34, 33, and 32 respectively. A plurality of control gates CG are formed by stacking the patterned second polysilicon layer 33 and the patterned tungsten silicide layer 34.

In accordance with the present invention, during forming a flash memory device, the floating gates are formed as the recess floating gates 31A buried into the recess patterns 29B and thus, an effective gate length defined by each of the recess floating gates 31A becomes CH2. Herein, CH42 is longer than an effective gate length of a planar type gate structure by a depth of the individual recess pattern 29B, i.e., twice the depth of the individual recess pattern 29B.

In accordance with the present invention, it is possible to increase an effective gate length if a flash memory device with a size of approximately sub 60 nm is fabricated using recess patterns, i.e., recess channels. Accordingly, an electrical property of the device can be improved without increasing a doping concentration of a substrate.

The present application contains subject matter related to the Korean patent application No. KR 2005-0115670, filed in the Korean Patent Office on Nov. 30, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a flash memory device, comprising:
forming a plurality of device isolation layers with a trench structure and a height greater than that of a surface of an active region in a substrate;
forming a plurality of recess patterns by etching regions in which floating gates are to be formed in the active region between the device isolation layers to a predetermined depth;
forming a tunnel oxide layer over the recess patterns;
forming a plurality of recessed floating gates buried into the recess patterns over the tunnel oxide layer; and
forming a plurality of stack structures by stacking a plurality of dielectric layers and a plurality of control gates in a direction perpendicular to the device isolation layers to cover upper portions of the recessed floating gates.

2. The method of claim 1, wherein the forming of the plurality of recess patterns includes:
forming a photoresist layer over the device isolation layers;
performing a photo-exposure process and a developing process to the photoresist layer to form a line type recess mask opening the portions in which the floating gates are to be formed;
etching the opened portions in which the floating gates are to be formed by using the recess mask as an etch mask, thereby forming the recess patterns; and
stripping the recess mask.

3. The method of claim 2, wherein the etching of the opened portions includes using a fluorine-based gas as etchant.

4. The method of claim 3, wherein the fluorine-base gas includes one selected from the group consisting of CF₄ gas, C₂F₆ gas, C₄F₈ gas, C₄F₆ gas, C₅F₈ gas, CF₃H gas, CF₂H₂ gas, CFH₃ gas, C₂HF₅ gas, NF₃ gas, SF₆ gas, and CF₃C1 gas.

5. The method of claim 4, wherein one of H₂ gas and O₂ gas is added to the fluorine-based gas.

6. The method of claim 2, wherein the etching of the opened portions includes an etch target ranging from approximately 800 Å to approximately 1,500 Å.

7. The method of claim 1, wherein the forming of the plurality of recessed floating gates includes:
forming a conductive layer over the tunnel oxide layer until the recess patterns are filled; and
planarizing the conductive layer until the tunnel oxide layer existing over portions except the recess patterns is exposed, thereby forming the recessed floating gates inside the recess patterns.

8. The method of claim 7, wherein the forming of the conductive layer includes depositing silicon with a thickness ranging from approximately 1,000 Å to approximately 2,000 Å.

9. The method of claim 8, wherein the planarizing of the conductive layer includes performing a polysilicon chemical mechanical polishing (CMP) process.

10. The method of claim 9, wherein the polysilicon CMP process uses slurry having a high etch selectivity of polysilicon to an oxide layer.

11. The method of claim 10, wherein the slurry has an etch selectivity of approximately 200 to approximately 300 parts of polysilicon to approximately 1 part of a tunnel oxide layer.

12. The method of claim 1, wherein the forming of the plurality of device isolation layers includes:
forming a trench mask over the substrate;
etching the substrate to a predetermined thickness by using the trench mask as an etch mask, thereby forming a plurality of trenches defining the active region;
forming a gap-fill insulation layer for device isolation in the trenches;
planarizing the gap-fill insulation layer until a surface of the trench mask is exposed; and
removing the trench mask.

13. The method of claim 12, wherein the planarizing of the gap-fill insulation layer includes sequentially employing a first CMP process using silica slurry and a second CMP process using ceria slurry.

14. The method of claim 13, wherein the forming of the trench mask includes sequentially stacking an oxide layer and a nitride layer.

15. The method of claim 14, wherein the removing of the trench mask includes:
removing the gap-fill insulation layer remaining over an upper portion of the trench mask after planarizing the gap-filled insulation layer;
stripping the nitride layer of the trench mask; and
stripping the oxide layer of the trench mask.

16. The method of claim 15, wherein the remaining gap-filled insulation layer is dipped into a buffered oxide etchant (BOE) to be removed; the nitride layer is stripped by using a solution of phosphoric acid (H₃PO₄); and the oxide layer is stripped by using a solution of hydrogen fluoride (HF).

17. The method of claim 1, wherein the forming of the plurality of stack structures includes:
forming the dielectric layers over the recessed floating gates;
forming a conductive layer for the control gates over the dielectric layers;
forming a silicon oxynitride layer over the conductive layer for the control gates;
forming a hard mask oxide layer over the silicon oxynitride layer;
forming a control gate mask over the hard mask oxide layer;
etching the hard mask oxide layer, the silicon oxynitride layer, the conductive layer for the control gates and the dielectric layer by using the control gate mask as an etch mask; and
removing the control gate mask.

18. The method of claim 17, wherein the forming of the conductive layer for the control gates includes stacking polysilicon and tungsten silicide.
